(19) United States
(12) Patent Application Publication
(10) Pub. No.: US 2009/0006911 A1
(43) Pub. Date: Jan. 1, 2009

(54) DATA REPLACEMENT PROCESSING METHOD

(75) Inventors: Tso-lin Wang, Tainan City (TW); Chun-ying Chiang, Chiayi City (TW); Kuo-chang Li, Hsinchu City (TW)

Correspondence Address: MADSON & AUSTIN, 15 WEST SOUTH TEMPLE, SUITE 900, SALT LAKE CITY, UT, 84101, US

(73) Assignee: MEDIATEK Inc., Hsin-Chu City (TW)

(21) Appl. No.: 11/770,518

(22) Filed: Jun. 28, 2007

(51) Int. Cl. G11C 29/04; G06F 11/30

(52) U.S. Cl. 714/711; 714/47; 714/E11.023; 714/E11.179

(57) ABSTRACT

A data replacement processing method is disclosed. In the present invention, buffering and decoding are not interrupted when a data block to be replaced is found. The data block to be replaced can be a defect or a remapped block. The data block to be replaced is not processed until it is requested to be transferred. When the data block to be replaced is to be transferred, transferring is stopped and the data block to be replaced is processed. Therefore, efficiency of the optical disc drive can be promoted since interruption number of the buffering and decoding is decreased. In addition, the optical disc will not execute redundant processing for data blocks to be replaced which are not requested to be transferred.

### TECHNICAL FIELD OF THE INVENTION

The present invention relates to data processing for an optical disc, more particularly, to processing of data replacement for a defect or remapped block of the optical disc.

### BACKGROUND OF THE INVENTION

In optical disc data processing, sometimes it is necessary to replace data of an original address by data of another address. For example, in jump recording mode of a −R dual layer disc, a replacing process is necessary for a remapped ECC block. In addition, a replacement is usually recorded in a spare area of the disc to replace a defect.

In reading or verifying written data from an optical disc, the data fetched from the optical disc is buffered to a main buffer of a disc drive, and the buffered data is then decoded. Finally, the decoded data is then transferred to a host when host requested. In the conventional scheme, buffering and/or decoding are stopped when a defect block or a known remapped block is read. The replacement for the defect or remapped block will be dealt with. A block can comprise a single sector.

In one prior art method, the block number of each buffered data block is monitored. If the block number matches a defect block number (defect ID) or a remapped block address, then buffering is stopped, as well as decoding. Replacement for the defect of remapped block is performed. For example, if replacement for the defect is recorded in a spare area of the optical disc, the buffering is stopped and the replacement is fetched to replace the defect. After the replacing process is finished, seeking must be re-executed so as to find the interrupted location where the buffering is to resume. That is, since the buffering is interrupted, it is necessary to re-seek to resume buffering. A pick-up head of the disc drive needs to shift back and forth. Accordingly, efficiency of the optical disc drive will be reduced.

In another prior art method, the disc drive monitors block number of a next block to be decoded. If the monitored block number matches a defect ID (or remapped block address), that is, it is found that the next block to be decoded is a defect (or remapped ECC block), then the decoding is stopped. After the replacing is processed, decoding is resumed.

In either of these two conventional methods, data block to be replaced such as a defect or remapped block is immediately processed once it is found. However, sometimes the data block to be replaced found during the buffering or decoding is not required to be transferred to the host. In this case, therefore, it is possible that the replacement processing for the data block to be replaced is redundant.

The present invention provides a solution to overcome the drawbacks described above.

### SUMMERY OF THE INVENTION

An aspect of the present invention is to provide a data replacement processing method. When a defective block (simply referred to as a “defect”) or a remapped ECC block is found as a data block to be replaced of an optical disc, the discovery of the data block to be replaced is ignored during buffer and decoding. Accordingly, buffering and decoding are not interrupted when the data block to be replaced is found. By using the method of the present invention, the buffering and decoding can be continued even when the data block to be replaced is found. Therefore, re-seeking operation times are reduced.

Another aspect of the present invention is to provide a data replacement processing method. When a defective block (simply referred to as a “defect”) or a remapped ECC block is found as a data block to be replaced in transferring decoded data of an optical disc, transferring is stopped and the data block to be replaced is processed. That is, the data block to be replaced is replaced by a replacement block. The data to be replaced is not processed until the data thereof is requested to be transferred according to the method of the present invention. Therefore, redundant processing of replacement is reduced or even avoided since only the data blocks, which needs to be replaced, to be transferred are processed.

Another aspect of the present invention is to provide a data replacement processing method. When a defective block (simply referred to as a “defect”) or a remapped ECC block is found as a data block to be replaced in decoding data of an optical disc, the discovery of the data block to be replaced is ignored, and no processing is executed for the data block to be replaced at this stage. When the defect or a remapped ECC block is found in transferring the decoded data, transferring is stopped and the data block to be replaced is processed. That is, the data block to be replaced is replaced by a replacement.

In accordance with an aspect of the present invention, the data replacement processing method includes obtaining data from an optical disc; buffering the obtained data into a buffer; decoding the buffered data; monitoring decoding process; and ignoring discovery of a data block to be replaced when the data to be replaced is found. That is, when a defect block or a remapped block is found during the decoding procedure, the decoded defect block or remapped block is ignored.

In accordance with another aspect of the present invention, the data replacement processing method includes obtaining data from an optical disc; buffering the obtained data into a buffer; decoding the buffered data; transferring the decoded data; monitoring transferring process; stopping transferring when a data block to be replaced is found in transferring monitoring; and processing the data to be replaced.

In accordance with a further aspect of the present invention, the data replacement processing method includes obtaining data from an optical disc; buffering the obtained data into a buffer; decoding the buffered data; transferring the decoded data; monitoring decoding process; monitoring transferring process; ignoring a data block to be replaced when the data block to be replaced is found in decoding monitoring; and stopping transferring when the data block to be replaced is found in transferring monitoring; and processing the data block to be replaced.

### BRIEF DESCRIPTION OF THE DRAWINGS

The present invention will be further described in details in conjunction with the accompanying drawings, wherein:

FIG. 1 is a flow chart showing a method in accordance with the present invention;

FIG. 2 is a block diagram generally and schematically showing a decoding auto-mask device in accordance with an embodiment of the present invention; and

FIG. 3 is a block diagram generally and schematically showing a transferring auto-stop device in accordance with an embodiment of the present invention.

### DETAILED DESCRIPTION OF THE INVENTION

The present invention will be described in details in conjunction with the appending drawings.

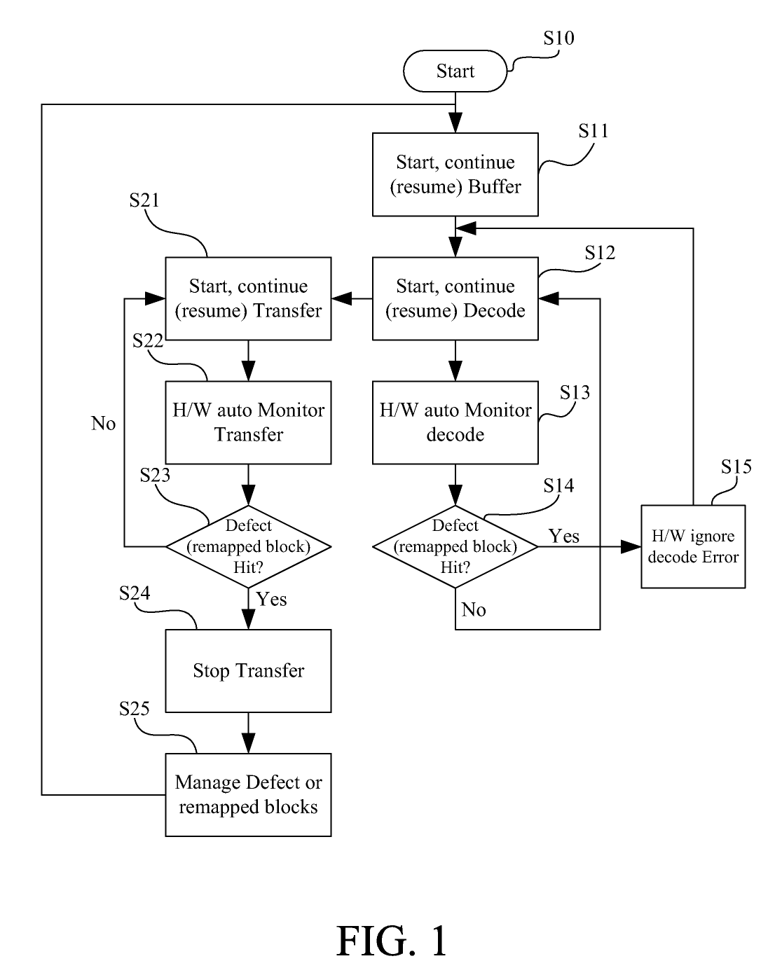

FIG. 1 is a flow chart showing a method in accordance with the present invention. The method is started at step S10. When an optical disc drive reading or verifying written data from an optical disc, data is obtained from the optical disc and buffered into a main buffer (not shown), as indicated by step S11. The buffered data is then decoded (step S12). In the present invention, decoding is monitored as indicated in step S13. For example, data blocks to be decoded are monitored. However, the decoding monitoring is continuously executed throughout the whole process of the method in practice. If a data block such as a defect is found, that is so called “defect hit” (step S14), the buffering and decoding are not interrupted. The buffering and decoding continue without interruption. Accordingly, the number of re-seeking operations can be reduced so as to lift the efficiency of the optical disc drive. When there is a defect hit, certain action is required to make the optical disc drive ignore the decode error (step S15), thereby avoid buffering and decoding interruptions. The relative details will be further described later. The respective steps are the same for the condition that the data block to be replaced is a remapped block.

As mentioned, the decoded data is usually to be transferred to a host (not shown) (step S21). In the present invention, the transferring is also monitored. (step S22). It is noted that the transfer monitoring is also continuously executed throughout the whole process. For example, data blocks to be transferred are monitored. When it is found that the block to be transferred is a data block to be replaced, for example, if the block to be transferred is a defect or a remapped block, then transferring is stopped (step S24). When the data block to be replaced is to be transferred, that is, this block is supposedly or indeed requested by the host, then the optical disc drive processes this block (defect or remapped block) (step S25).

The disc drive reads data of a replacement to replace the block to be replaced. If the replacement data has been stored in a reserve buffer (not shown), then it can be copied from the reserve buffer to the main buffer, thus the optical disc drive needs not to stop buffering and decoding, and needs not to seek the location of the replacement in the spare area of the disc. If the replacement data is not stored in a buffer, then the optical disc drive may need to stop buffering and decoding so as to seek the location of the replacement in the spare area of the disc and read the data thereof. After transferring is stopped, the time required to process the defect (remapped block) may be different in various conditions. For example, it is preferred that the disc drive processes the defect immediately in random reading mode. In sequential reading mode, the defect processing is preferably held until the defects are accumulated to a predetermined number. It is noted that the disc drive only executes replacement processing under the request of host according to the present invention. That is, the disc drive only processes the data blocks to be replaced that are to be transferred. Therefore, the processing for the defect or remapped block will not be redundant.

As described, when a data block to be replaced such as a defect or remapped block is found in decoding monitoring process, according to the present invention, the disc drive ignores the discovery of the data block to be replaced, so that buffering and decoding are not interrupted. That is, the decoded defect or remapped block is ignored. One way is to mask the decoded defect or remapped block, so that the masked defect or remapped block will not be processed. In addition, a decode error interruption signal, which is generated when there is a data block to be replaced found to a processor (not shown) of the optical disc drive, thereby masking the request to interrupt buffering and decoding. By doing so, the buffering and decoding will not be interrupted.

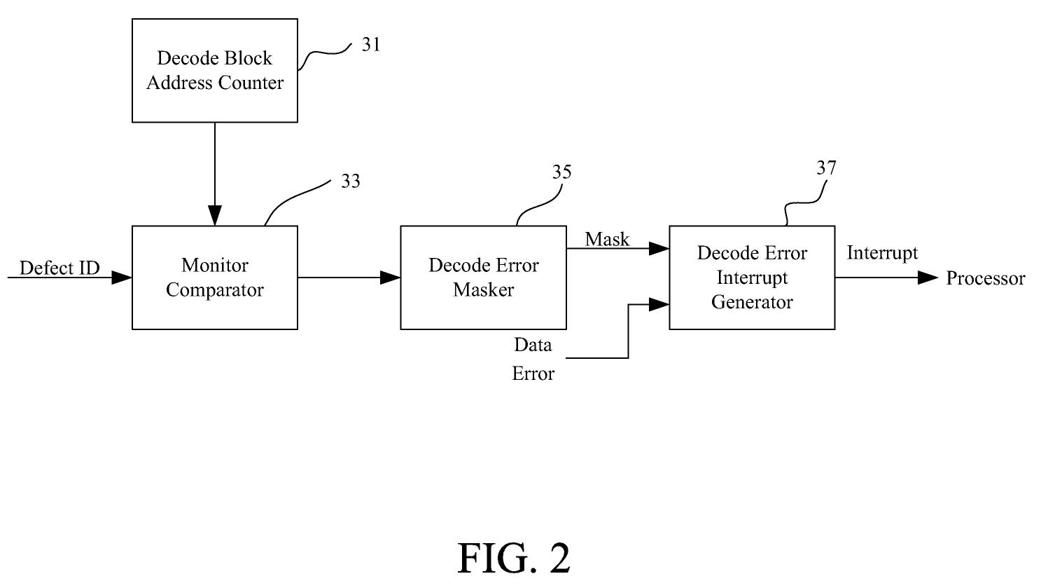

FIG. 2 shows a decoding auto-mask device in accordance with an embodiment of the present invention. The auto-mask device includes a decode block address counter 31. The decode block address counter counts the decoded blocks, increases the count by one after a block has been decoded, and generates a block ID for the next block to be decoded. In addition, the auto-mask device has a monitor comparator 33. The monitor comparator 33 compares the block ID generated by the decode block address counter 31 with defect IDs stored in a defect table, or defect IDs from defects pre-stored in a DRAM, for example, to see if the next block to be decoded is a defect. Inherently, if the next block to be decoded is a defect, a decoding error signal will be sent to a decode error interrupt generator 37 to notify the discovery of the defect, so that the decode error interrupt generator 37 generates an interrupt signal and transmits the interrupt signal to the processor (not shown) to request the processor to stop decoding. However, in accordance with the embodiment of the present invention, the decoding auto-mask device further has a decode error masker 35 disposed between the monitor comparator 33 and the decode error interrupt generator 37. When the monitor comparator 33 outputs the decoding error signal notifying that there is a defect hit, the decode error masker 35 generates a mask signal and outputs this mask signal to the decode error interrupt generator 37. The mask signal requests the decode error interrupt generator 37 to ignore the decoding error. Accordingly, the decode error interrupt generator 37 will not transmit the interrupt signal, so that the decoding will not be interrupted. Although the defect is described herein as an example, the above operations are similar to a remapped block.

As mentioned above, when the data block to be replaced (e.g. a defect or a remapped block) is to be transferred in data transferring process, the transferring should be stopped, and the data block to be replaced should be processed in a proper timing.

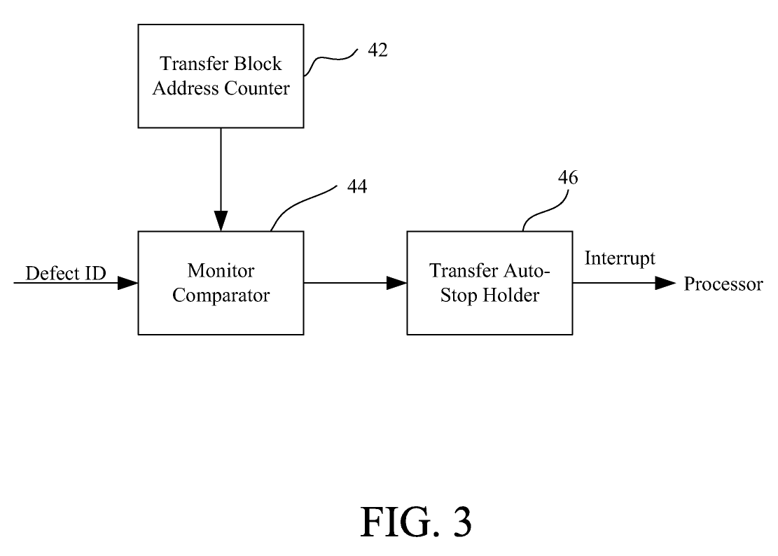

FIG. 3 shows a transferring auto-stop device in accordance with an embodiment of the present invention. The transferring auto-stop device includes a transfer block address counter 42, a monitor comparator 44 and a transfer auto-stop holder 46. The transfer block address counter 42 increases a count by one whenever a block is transferred to the host, and generates a transfer block ID for the next block to be transferred. The monitor comparator 44 compares the transfer block ID generated by the transfer block address counter 42 with defect IDs. If the transfer block ID matches one of the defect IDs, it means that the block indicated by the transfer block ID is a defect, which is referred to as “defect hit”. The monitor comparator 44 transmits a transferring error signal to the transfer auto-stop holder 46. The transfer auto-stop holder 46 holds the data of the next block, which is a defect, and waits until the end of the block being transferred, then generates a transfer stop signal to stop transferring. Also, though the defect is described herein as an example, the above operations are similar to a remapped block.

As described above, the disc drive should process the defect (or remapped block) after the transferring is stopped, since the data of the defect is requested or supposed to be requested by the host. The disc drive fetches data of a corresponding replacement to replace the defect. If the data of the replacement (simply referred to as replacement data) has been stored in the reserve buffer or another memory, the disc drive can simply copy the replacement data to use. Otherwise, the disc drive may need to move the pick-up head (not shown) to fetch the replacement data, which is usually allocated in a spare area of the disc. Since the pick-up head is moved to seek the replace data, the buffering and decoding must be interrupted.

As mentioned, in the embodiment, the present invention is described by mainly using the defect as the example, it can also be applicable for the remapped block or any other kind of data block to be replaced by data recorded in another address.

While the preferred embodiments of the present invention have been illustrated and described in details, various modifications and alterations can be made by persons skilled in this art. The embodiments of the present invention are therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A data replacement processing method comprising steps of:
obtaining data from an optical disc;
buffering the obtained data;
decoding the buffered data;
monitoring data to be decoded; and
ignoring discovery of a data block to be replaced if the data block to be replaced is found in decoding monitoring.

2. The method of claim 1, wherein the data block to be replaced is a defect or a remapped block.

3. The method of claim 1, wherein it is checked if a next data block to be decoded is a data block to be replaced in the monitoring step.

4. The method of claim 3, wherein the next data block to be decoded is checked by comparing a block number thereof with information of known data blocks to be replaced.

5. The method of claim 1 wherein interruption of buffer and decoding are eliminated when finding the data block to be replaced in the ignoring step.

6. The method of claim 5, wherein an interrupt signal instructing interruption of buffering and decoding when finding the data block to be replaced is masked in the ignoring step.

7. The method of claim 1, wherein the data block to be replaced is masked in the ignoring step.

8. A data replacement processing method comprising steps of:
obtaining data from an optical disc;
transferring the data;
monitoring data to be transferred; and
stopping transferring if a data block to be replaced is found.

9. The method of claim 8, wherein the data block to be replaced is a defect or a remapped block.

10. The method of claim 8, wherein it is checked if a next data block to be transferred is a data block to be replaced in the monitoring step.

11. The method of claim 10, wherein the next data block to be transferred is checked by comparing a block number thereof with information of known data blocks to be replaced.

12. A data replacement processing method comprising steps of:
obtaining data from an optical disc;
buffering the obtained data;
decoding the buffered data;
monitoring data to be decoded;
ignoring discovery of a data block to be replaced if the data block to be replaced is found in monitoring data to be decoded;
transferring the decoded data;
monitoring data to be transferred; and
stopping transferring if a data block to be replaced is found in monitoring data to transferred.

13. The method of claim 12, wherein the data block to be replaced is a defect or a remapped block.

14. The method of claim 12, wherein it is checked if a next data block to be decoded is a data block to be replaced in monitoring data to be decoded.

15. The method of claim 14, wherein the next data block to be decoded is checked by comparing a block number thereof with information of known data blocks to be replaced.

16. The method of claim 12 wherein interruption of buffer and decoding are eliminated when finding the data block to be replaced in the ignoring step.

17. The method of claim 16, wherein an interrupt signal instructing interruption of buffering and decoding when finding the data block to be replaced is masked in the ignoring step.

18. The method of claim 12, wherein it is checked if a next data block to be transferred is a data block to be replaced in the monitoring step.

19. The method of claim 18, wherein the next data block to be transferred is checked by comparing a block number thereof with information of known data blocks to be replaced.

20. The method of claim 12, wherein the data block to be replaced is masked in the ignoring step.
